(19) United States
(12) Patent Application Publication
(10) Pub. No.: US 2026/0177622 A1
(43) Pub. Date: Jun. 25, 2026

(54) JIG FOR EVALUATING BATTERY CELL

(71) Applicant: SAMSUNG SDI CO., LTD., Yongin-si (KR)

(72) Inventor: Chanlan YANG, Yongin-si (KR)

(21) Appl. No.: 19/269,266

(22) Filed: Jul. 15, 2025

(30) Foreign Application Priority Data
Dec. 23, 2024 (KR) 10-2024-0193707

(51) Int. Cl. G01R 31/36; H01M 10/42

(52) U.S. Cl. CPC G01R 31/3644; H01M 10/4285

(57) ABSTRACT

A jig for evaluating a battery cell includes first plates arranged to face each other, a spacer that fixes the first plates to each other, second plates arranged to face each other, the second plates being between the first plates, and the second plates defining a space therebetween to accommodate a battery cell to be in contact with the second plates, and an elastic member interposed between each of the first plates and a corresponding one of the second plates.

### CROSS-REFERENCE TO RELATED APPLICATION

This application claims priority under 35 U.S.C. § 119 to Korean Patent Application No. 10-2024-0193707, filed in the Korean Intellectual Property Office on Dec. 23, 2024, the entire contents of which are hereby incorporated by reference.

### BACKGROUND

### 1. Field

The present disclosure relates to a jig for evaluating a battery cell.

### 2. Description of the Related Art

Unlike primary batteries that are not designed to be (re)charged, secondary (or rechargeable) batteries are batteries that are designed to be discharged and recharged. Low-capacity secondary batteries are used in portable, small electronic devices, such as smart phones, feature phones, notebook computers, digital cameras, and camcorders, while large-capacity secondary batteries are widely used as power sources for driving motors in hybrid vehicles and electric vehicles and for storing power (e.g., home and/or utility scale power storage). A secondary battery generally includes an electrode assembly composed of a positive electrode and a negative electrode, a case accommodating the same, and electrode terminals connected to the electrode assembly.

A secondary battery may undergo a charging and discharging process and a performance evaluation process for battery activation. The charging and discharging process and performance evaluation process may be performed by mounting the secondary battery in a secondary battery charging and discharging device.

The above information disclosed in this Background section is for enhancement of understanding of the present disclosure, and therefore, it may contain information that does not constitute related (or prior) art.

### SUMMARY

According to an embodiment of the present disclosure, a jig for evaluating a battery cell may include a battery cell, first plates arranged to face each other with the battery cell interposed therebetween, a spacer that fixes the first plates, second plates arranged to be in close contact with both sides of the battery cell, and an elastic member interposed between the first plate and the second plate.

According to an embodiment, the battery cell may include mutually facing long sidewall portions and mutually facing short sidewall portions, and an area of the long sidewall portions may be greater than an area of the short sidewall portions.

According to an embodiment, the first plate may include a metallic material.

According to an embodiment, the first plate may be arranged so as to face the long sidewall portions.

According to an embodiment, an area of a surface of the second plate that faces the battery cell may be greater than or equal to an area of the long sidewall portions.

According to an embodiment, the second plate may be arranged so as to be in close contact with the long sidewall portions.

According to an embodiment, the second plate may include at least one of a metallic material and an insulating material.

According to an embodiment, when the battery cell is charged and discharged, the elastic member may generate an elastic force in an opposite direction against movement of the second plate caused by a volumetric change of the battery cell.

According to an embodiment, the elastic member may include at least one spring.

According to an embodiment, the elastic member may include an elastic material.

According to an embodiment, the jig for evaluating a battery cell may further include a third plate arranged between the short sidewall portions of the battery cell and the spacer, and which is in close contact with the short sidewall portions.

According to an embodiment, the third plate may include an insulating material.

According to an embodiment, the first plate may include at least one insertion groove under the battery cell, the at least one insertion groove recessed in a direction in which the first plates face each other.

According to an embodiment, the jig for evaluating a battery cell may further include a fourth plate inserted into the insertion groove and arranged to support the battery cell.

According to an embodiment, the fourth plate may include an insulating material.

According to an embodiment, each of the second plate, the third plate, and the fourth plate may include an inlet into which a coolant is introduced, a passage through which the introduced coolant flows, and an outlet through which the coolant is discharged from the passage.

According to an embodiment, the jig for evaluating a battery cell may further include a cooling device that is connected to each inlet and outlet of the second plate, the third plate, and the fourth plate.

According to an embodiment, the inlets and outlets of each of the second plate, the third plate, and the fourth plate may be connected such that the coolant may flow continuously through the passage of the second plate, the passage of the third plate, and the passage of the fourth plate, and the jig for evaluating a battery cell may further include a cooling device that is connected to the inlet and outlet of any one of the second plate, the third plate, and the fourth plate.

According to an embodiment, the jig for evaluating a battery cell may be symmetrical about a center line of the battery cell with respect to a direction intersecting the direction in which the first plates faces each other.

According to an embodiment, the battery cell may include a pouch-type cell or a prismatic cell.

### BRIEF DESCRIPTION OF DRAWINGS

The following drawings attached to this specification illustrate embodiments of the present disclosure and, together with the detailed description of the present disclosure, will further clarify aspects and features of the present disclosure. Thus, the present disclosure should not be construed as being limited to the drawings.

FIG. 1 is a perspective view illustrating an example of a jig for evaluating a battery cell according to an embodiment of the present disclosure.

FIG. 2 is a plan view illustrating an example of a jig for evaluating a battery cell according to an embodiment of the present disclosure.

FIG. 3 is a perspective view illustrating an example of a battery cell according to an embodiment of the present disclosure.

FIG. 4 is a plan view illustrating an example of the jig for evaluating a battery cell according to an embodiment of the present disclosure when the battery cell is charged and discharged.

FIG. 5 is a plan view illustrating an example of a jig for evaluating a battery cell, which further includes a third plate, according to an embodiment of the present disclosure.

FIG. 6 is a plan view illustrating an example of the jig for evaluating a battery cell, which further includes a third plate, according to an embodiment of the present disclosure when the battery cell is charged and discharged.

FIG. 7 is a side view illustrating an example of the jig for evaluating a battery cell, which further includes a fourth plate, according to an embodiment of the present disclosure.

FIG. 8 is a diagram illustrating an example of the jig for evaluating a battery cell, which further includes a cooling device, according to an embodiment of the present disclosure.

FIG. 9 is a plan view illustrating an example of the second plate according to an embodiment of the present disclosure.

FIG. 10 is a plan view illustrating an example of the third plate according to an embodiment of the present disclosure.

FIG. 11 is a plan view illustrating an example of the fourth plate according to an embodiment of the present disclosure.

FIG. 12 is a diagram illustrating an example of the jig for evaluating a battery cell, which further includes a cooling device and a connecting pipe, according to an embodiment of the present disclosure.

### DETAILED DESCRIPTION

Hereinafter, embodiments of the present disclosure will be described in detail with reference to the accompanying drawings. The terms or words used in this specification and claims should not be construed as being limited to their usual or dictionary meanings and should be interpreted as meanings and concepts consistent with the technical idea of the present disclosure, based on the principle that an inventor can define his/her own terms appropriately to best describe the invention.

The embodiments described in this specification and the configurations shown in the drawings are only some examples of the present disclosure and do not represent all of the technical ideas, aspects, or features of the present disclosure. Accordingly, it should be understood that there may be various equivalents and modifications that can replace or modify the embodiments described herein at the time of filing this application.

It will be understood that when an element or layer is referred to as being “on,” “connected to,” or “coupled to” another element or layer, it may be directly on, connected, or coupled to the other element or layer, or one or more intervening elements or layers may be present. When an element or layer is referred to as being “directly on,” “directly connected to,” or “directly coupled to” another element or layer, there are no intervening elements or layers. For example, when a first element is described as being “coupled” or “connected” to a second element, the first element may be directly coupled or connected to the second element, or the first element may be indirectly coupled or connected to the second element via one or more intervening elements.

In the figures, dimensions of the various elements, layers, etc. may be exaggerated for clarity of illustration. The same reference numerals designate the same elements. As used herein, the term “and/or” includes any and all combinations of one or more of the associated listed items. Further, the use of “may” when describing embodiments of the present disclosure relates to “one or more embodiments of the present disclosure.” Expressions such as “at least one of” and “any one of,” when preceding a list of elements, modify the entire list of elements, not just an individual element in the list. When phrases such as “at least one of A, B and C,” “at least one of A, B or C,” “at least one selected from a group of A, B and C,” or “at least one selected from among A, B and C” are used to designate a list of elements A, B and C, the phrase may refer to any suitable combination or subset of A, B and C, such as A, B, C, A and B, A and C, B and C, or A and B and C. As used herein, the terms “use,” “using,” and “used” may be considered synonymous with the terms “utilize,” “utilizing,” and “utilized,” respectively. As used herein, the terms “substantially,” “about,” and similar terms are used as terms of approximation, not as terms of degree, and are intended to account for the inherent variations in measured or calculated values recognized by those of ordinary skill in the art.

It will be understood that, although the terms first, second, third, etc. may be used herein to describe various elements, components, regions, layers, and/or sections, these terms are used only to distinguish one element, component, region, layer, or section from another. Thus, a first element, component, region, layer, or section discussed below could be termed a second element, component, region, layer, or section without departing from the teachings of example embodiments.

Spatially relative terms, such as “beneath,” “below,” “lower,” “above,” “upper,” and the like, may be used herein for ease of description to describe one element or feature's relationship to another element(s) or feature(s) as illustrated in the figures. It will be understood that the spatially relative terms are intended to encompass different orientations of the device in use or operation in addition to the orientation depicted in the figures. For example, if the device in the figures is turned over, elements described as “below” or “beneath” other elements or features would then be oriented “above” or “over” the other elements or features. Thus, the term “below” may encompass both an orientation of above and below. The device may be otherwise oriented (rotated 90 degrees or at other orientations), and the spatially relative descriptors used herein should be interpreted accordingly.

The terminology used herein is for the purpose of describing embodiments of the present disclosure and is not intended to limit the present disclosure. As used herein, the singular forms “a” and “an” are intended to include the plural forms as well, unless the context clearly indicates otherwise. Also, when used in this specification, the terms “includes,” “including,” “comprises,” and/or “comprising” specify the presence of stated features, integers, steps, operations, elements, and/or components but do not preclude the presence or addition of one or more other features, integers, steps, operations, elements, components, and/or groups thereof.

Also, any numerical range disclosed and/or recited herein is intended to include all subranges of the same numerical precision subsumed within the recited range. For example, a range of “1.0 to 10.0” is intended to include all subranges between (and including) 1.0 and 10.0, such as 2.4 to 7.6. Any maximum numerical limitation recited herein is intended to include all lower numerical limitations subsumed therein, and any minimum numerical limitation recited in this specification is intended to include all higher numerical limitations subsumed therein. Accordingly, Applicant reserves the right to amend this specification, including the claims, to expressly recite any subrange subsumed within the ranges expressly recited herein. All such ranges are intended to be inherently described in this specification such that amending to expressly recite any such subranges would comply with the requirements of 35 U.S.C. § 112(a) and 35 U.S.C. §132(a).

References to two compared elements, features, etc. as being “the same” may mean that they are “substantially the same.” The phrase “substantially the same” may include a case having a deviation that is considered low in the art, for example, a deviation of 5% or less. In addition, when a certain parameter is referred to as being uniform in a given region, it may mean that it is uniform in terms of an average.

Throughout the specification, unless otherwise stated, each element may be singular or plural.

Arranging an arbitrary element “above (or below)” or “on (under)” another element may mean that the arbitrary element may be disposed in contact with the upper (or lower) surface of the other element, and another element may also be interposed between the element and the arbitrary element disposed on (or under) the other element.

In addition, it will be understood that when a component is referred to as being “linked,” “coupled,” or “connected” to another component, these elements may be directly “coupled,” “linked,” or “connected” to each other, or another component may be “interposed” between those components.

Throughout the specification, when “A and/or B” is stated, it means A, B, or A and B, unless otherwise stated. That is, “and/or” includes any or all combinations of a plurality of items enumerated. When “C to D” is stated, it means C or greater and D or less, unless otherwise specified.

In the present disclosure, the sizes and relative sizes of layers and areas shown in the figures may be exaggerated for clarity of illustration. Also, the same reference numerals throughout the specification denote the same components.

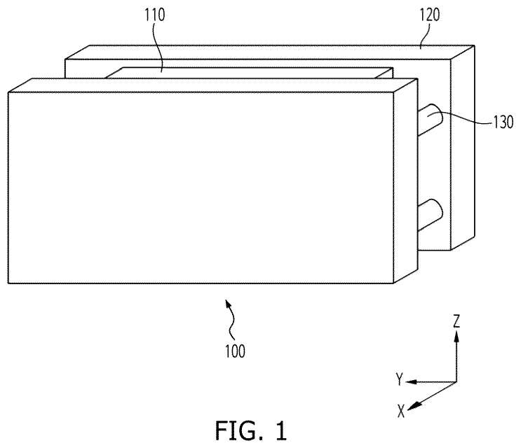

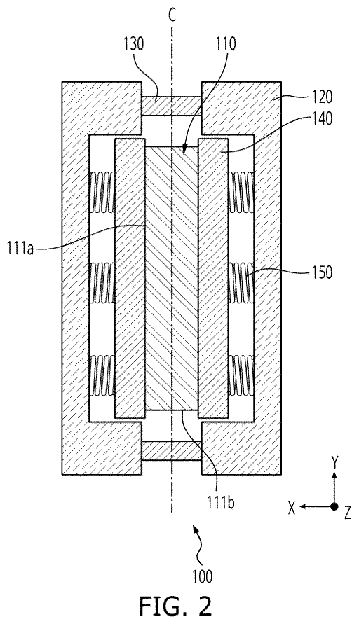

FIG. 1 is a perspective view illustrating an example of a jig for evaluating a battery cell according to an embodiment of the present disclosure, and FIG. 2 is a plan view of the jig in FIG. 1.

Referring to FIGS. 1 and 2, a jig 100 for evaluating a battery cell may include a battery cell 110, a first plate 120, a spacer 130, a second plate 140, and an elastic member 150.

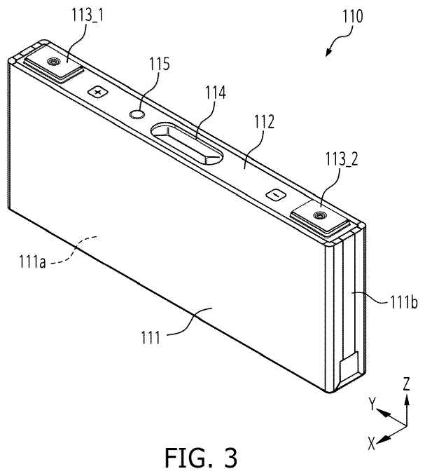

The battery cell 110 may include mutually facing long sidewall portions 111a and mutually facing short sidewall portions 111b, and an area of the long sidewall portions 111a may be greater than an area of the short sidewall portions 111b. Details regarding this are described below with reference to FIG. 3.

A pair of first plates 120 may be provided so as to face each other with the battery cell 110 interposed therebetween (e.g., the pair of first plates 120 may extend lengthwise in the Y-axis direction and in parallel to each other, while being spaced apart from each other in the X-axis direction to provide a space therebetween for the battery cell 110). In detail, the first plates 120 may be arranged so that they face each other in the X-axis direction with the battery cell 110 in between. According to an embodiment, the first plates 120 may be arranged so as to face the long sidewall portions 111a of the battery cell 110. That is, the first plates 120 may be arranged so as to face the long sidewall portions 111a in the X-axis direction.

The material and thickness of the first plates 120 may be set in consideration of rigidity. According to an embodiment, the first plates 120 may include a metallic material. The metallic material may be a material having rigidity sufficient to not deform under the volumetric changes of the battery cell 110 during charging and discharging. However, the material of the first plates 120 may vary, and any material having sufficient rigidity to avoid deformation under the volumetric changes of the battery cell 110 during charging and discharging may be used.

The spacer 130 may fix the first plates 120. The spacer 130 may be cylindrical and may include at least one pair. The spacer 130 may be disposed between both ends of the pair of first plates 120 so as to fix the pair of first plates 120 at a certain distance from each other. For example, referring to FIG. 2, the spacer 130 may extend lengthwise in the X-axis direction to connect (e.g., directly connect) between facing edges of the pair of first plates 120. For example, referring to FIG. 2, a pair of spacers 130 may be spaced apart from each other in the Y-axis direction to be at opposite ends of the jig 100.

A pair of second plates 140 may be provided so as to be arranged in close contact (e.g., direct contact) with both sides (e.g., opposite sides) of the battery cell 110. In detail, the second plates 140 may be arranged so that they face each other in the X-axis direction with the battery cell 110 in between. According to an embodiment, the second plates 140 may be arranged to be in close contact (e.g., direct contact) with the long sidewall portions 111a of the battery cell 110. For example, referring to FIG. 2, the pair of second plates 140 may extend lengthwise in the Y-axis direction and in parallel to each other, while being spaced apart from each other in the X-axis direction to provide a space therebetween for the battery cell 110. For example, referring to FIG. 2, each of the pair of second plates 140 may be between the battery cell 110 and a corresponding one of the pair of first plates 120.

According to an embodiment, an area of a surface of the second plate 140 facing the battery cell 110 may be greater than or equal to an area of the long sidewall portions 111a. A length of the second plate 140 (e.g., in the Y-axis direction) may be greater than or equal to a length of the battery cell 110, and a height of the second plate 140 (e.g., in the Z-axis direction) may be greater than or equal to a height of the battery cell 110. Specifically, with respect to the Y-axis direction, the length of the second plate 140 may be greater than or equal to the length of the battery cell 110, and with respect to the Z-axis direction, the length of the second plate 140 may be greater than or equal to the length of the battery cell 110.

According to an embodiment, the second plate 140 may include at least one of a metallic material and an insulating material. The metallic material may be a material having rigidity sufficient to not deform under the volumetric changes of the battery cell 110 during charging and discharging. The insulating material may be a material having a resistance such that electricity does not flow through contact with the battery cell 110, and it may also be a material capable of absorbing heat from the battery cell 110.

The elastic member 150 may be interposed between each of the first plates 120 and a corresponding on of the second plates 140. According to an embodiment, the elastic member 150 may include at least one spring. The spring may be supported by the first plates 120 and the second plates 140, and fixed between the first plates 120 and the second plates 140.

According to an embodiment, the elastic member 150 may include an elastic material. The elastic material may be a material that, when deformed by an external force, returns to its original shape once the force is removed. For example, the elastic material may include rubber, elastic polyurethane, or silicone.

The size and number of the elastic members 150 may be determined in consideration of the size of the battery cell 110. Therefore, by adjusting the size and number of the elastic members 150, it may be possible to adjust the magnitude of stress transmitted to the battery cell 110. In addition, by adjusting the distance between the first plates 120 and the second plates 140, it may be possible to adjust the amount of heat absorption from the battery cell 110 by the second plates 140.

The elastic member 150 may be arranged in consideration of volumetric changes of the battery cell 110 during charging and discharging. When the battery cell 110 is charged and discharged, the volumetric change in a central region of the battery cell 110 may be relatively large. Accordingly, the elastic member 150 may be arranged at the center of the battery cell 110. In this case, the elastic member 150 may be arranged symmetrically about the centrally arranged elastic member 150. Furthermore, the elastic modulus of the elastic member 150 arranged at the center of the battery cell 110 may differ from the elastic modulus of the elastic members 150 arranged in other regions. As a result, stress due to the volumetric changes of the battery cell 110 during charging and discharging may be uniformly distributed over the entire surface of the long sidewall portions 111a of the battery cell 110 by the elastic member 150.

According to an embodiment, the jig 100 for evaluating a battery cell may be symmetrical about a center line C of the battery cell 110, the center line C being perpendicular to the direction (the X-axis direction) in which the first plates 120 face each other. That is, the center line C of the battery cell 110 may be parallel to the Y-axis direction. Consequently, during charging and discharging, the stress caused by the volumetric change of the battery cell 110 may be applied evenly to both sides of the battery cell 110.

FIG. 3 is a perspective view illustrating an example of the battery cell according to an embodiment of the present disclosure.

Referring to FIG. 3, the battery cell 110 may include at least one electrode assembly in which a positive electrode and a negative electrode are wound or stacked with a separator interposed therebetween, the separator being an insulator. The battery cell 110 may also include a case 111 in which the electrode assembly is accommodated, and a cap plate 112 coupled to one open end of the case 111. FIG. 3 illustrates an example where the battery cell 110 is a prismatic secondary battery, but the battery cell 110 may include various other types of secondary batteries.

Each of the positive electrode and the negative electrode may include a current collector made of a thin metal foil having a coated portion on which an active material is coated and an uncoated portion on which an active material is not coated. The positive electrode and the negative electrode may be wound with a separator, which is an insulator, interposed therebetween. However, the present disclosure is not limited thereto, and the electrode assembly may have a structure in which a plurality of positive electrodes and negative electrodes are alternately stacked with a separator interposed therebetween.

A positive electrode for a rechargeable lithium battery may include a current collector and a positive electrode active material layer on the current collector. The positive electrode active material layer may include a positive electrode active material and may further include a binder and/or a conductive material (e.g., an electrically conductive material).

The separator may include polyethylene, polypropylene, polyvinylidene fluoride, or a multilayer film of two or more layers thereof, and a mixed multilayer film such as a polyethylene/polypropylene two-layer separator, a polyethylene/polypropylene/polyethylene three-layer separator, a polypropylene/polyethylene/polypropylene three-layer separator, and the like.

A negative electrode for a rechargeable lithium battery may include a current collector and a negative electrode active material layer on the current collector. The negative electrode active material layer may include a negative electrode active material and may further include a binder and/or a conductive material (e.g., an electrically conductive material).

A positive electrode tab may be connected to one side of the positive electrode plate, and a negative electrode tab may be connected to one side of the negative electrode plate. The positive and negative electrode tabs may be electrically connected to a positive terminal 113_1 and a negative terminal 113_2 formed in the cap plate 112, respectively. The positive and negative terminals 113_1 and 113_2 formed in the cap plate 112 may be electrically connected to a busbar.

The case 111 may form the overall outer appearance of the battery cell 110 and may be made of a conductive metal such as aluminum, an aluminum alloy, or nickel-plated steel. In addition, the case 111 may provide a space in which the electrode assembly is accommodated. According to an embodiment of the present disclosure, the case 111 may be a prismatic case, and the battery cell 110 may be a prismatic battery cell. However, the battery cell 110 may be any type of battery cell, such as prismatic, cylindrical, or pouch-type.

According to an embodiment, the case 111 may include mutually facing long sidewall portions 111a and mutually facing short sidewall portions 111b. The long sidewall portions 111a may include a first long sidewall portion and a second long sidewall portion that face each other, spaced apart. The short sidewall portions 111b may include a first short sidewall portion and a second short sidewall portion that face each other, spaced apart. An area of the long sidewall portions 111a may be greater than an area of the short sidewall portions 111b.

The cap plate 112 may be coupled to the open end of the case 111 so as to seal the case 111. The case 111 and the cap plate 112 may be formed of conductive materials. According to an embodiment, an upper end of the case 111 may be open, and the cap plate 112 may seal the open upper end of the case 111.

The positive terminal 113_1, which is electrically connected to the positive electrode, and the negative terminal 113_2, which is electrically connected to the negative electrode, may be coupled to the cap plate 112. For example, the positive and negative terminals 113_1 and 113_2 may be installed so as to penetrate through the cap plate 112 and protrude outward.

A vent portion 114 may be formed on at least one surface of the battery cell 110. In the illustrated example, the vent portion 114 may be formed on an upper surface of the battery cell 110, that is, on the cap plate 112. The vent portion 114 may be configured to open when an internal pressure exceeding a predetermined critical pressure is detected in the battery cell 110.

The cap plate 112 may include an electrolyte inlet 115. For example, the electrolyte inlet 115 may be a through hole formed in the cap plate 112. After the cap plate 112 is coupled to the open portion of the case 111 and sealed, the electrolyte inlet 115 may be used to inject an electrolyte into the case 111. After the electrolyte is injected, the electrolyte inlet 115 may be sealed with a sealing member.

The battery cell 110 may be a lithium battery cell, a sodium battery cell, or the like. However, the battery cell 110 may be any battery capable of repeatedly providing electricity through charging and discharging. In an embodiment, when the battery cell 110 is a lithium battery cell, it may be used in electric vehicles (EVs) due to its excellent lifespan characteristics and high-rate characteristics. It may also be used in plug-in hybrid electric vehicles (PHEVs) and other hybrid vehicles, as well as in applications requiring high power storage, such as electric bicycles and electric power tools.

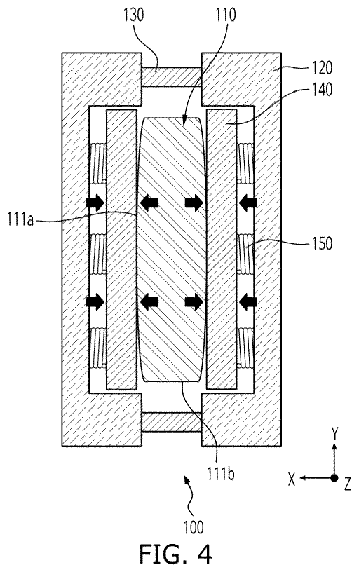

FIG. 4 is a plan view illustrating an example of the jig 100 for evaluating a battery cell according to an embodiment of the present disclosure when the battery cell is charged and discharged. Descriptions of components described with reference to FIGS. 1 and 2 are omitted here.

Referring to FIG. 4, the battery cell 110 may undergo volumetric changes during charging and discharging. In detail, the central portion of the battery cell 110 may experience a relatively large volumetric change when the battery cell 110 is charged and discharged.

According to an embodiment, when the battery cell 110 is charged and discharged, the elastic member 150 may generate an elastic force in the opposite direction against movement of the second plate 140 caused by the volumetric changes of the battery cell 110. For example, when the volumetric changes of the battery cell 110 during charging and discharging cause the second plate 140 to move outward, the second plate 140 may receive an inward elastic force from the elastic member 150. Here, “outward” may mean a direction away from the center of the battery cell 110 in the X-axis direction, and “inward” may mean a direction toward the center of the battery cell 110 in the X-axis direction.

Due to the structural characteristics of the elastic member 150 described above, stress caused by the volumetric changes of the battery cell 110 during charging and discharging may be uniformly distributed over the entire surface of the long sidewall portions 111a of the battery cell 110. As a result, the accuracy of performance evaluation of the battery cell 110 may be improved.

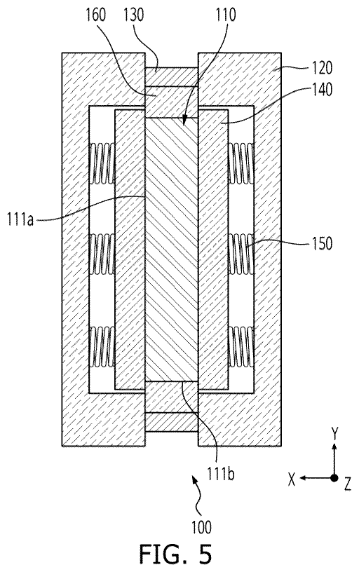

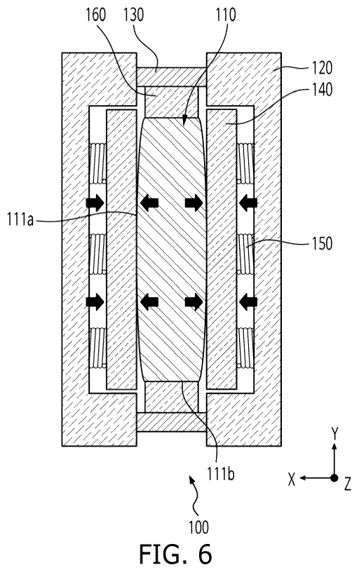

FIG. 5 is a plan view illustrating an example of a jig for evaluating a battery cell, which further includes a third plate, according to an embodiment of the present disclosure. FIG. 6 is a plan view illustrating an example of the jig in FIG. 5, when the battery cell is charged and discharged.

Referring to FIGS. 5 and 6, the jig 100 for evaluating a battery cell may further include a third plate 160, which is arranged between the short sidewall portions 111b of the battery cell 110 and the spacer 130 and is in close contact (e.g., direct contact) with the short sidewall portions 111b. The third plate 160 may be coupled to and fixed by the spacer 130. For example, referring to FIG. 5, the third plate 160 may extend lengthwise along the spacer 130 (e.g., while being in direct contact with the spacer 130), and may be in direct contact with each of the facing first plates 120.

According to an embodiment, the third plate 160 may include an insulating material. The insulating material may be a material having a resistance such that electricity does not flow through contact with the battery cell 110, and it may also be a material capable of absorbing heat from the battery cell 110.

According to an embodiment, the width of the third plate 160 may be greater than or equal to the thickness of the battery cell 110. Based on the X-axis direction, the length of the third plate 160 may be greater than or equal to the length of the battery cell 110.

Due to the structural characteristics of the third plate 160 described above, stress caused by the volumetric changes of the battery cell 110 during charging and discharging may be uniformly distributed over the entire surface of the short sidewall portions 111b of the battery cell 110 by the third plate 160. In addition, the third plate 160 may absorb heat generated by the battery cell 110. As a result, the accuracy of performance evaluation of the battery cell 110 may be improved.

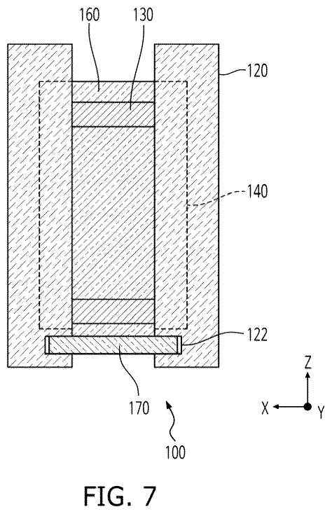

FIG. 7 is a side view illustrating an example of a jig for evaluating a battery cell, which further includes a fourth plate, according to an embodiment of the present disclosure. FIG. 7 is a view of the jig for evaluating a battery cell as seen from the Y-axis direction (i.e., looking in the Y-axis direction, when the Y-axis direction extends into the page).

Referring to FIG. 7, the first plates 120 may be formed such that at least one insertion groove 122 recessed in the X-axis direction (the direction in which the pair of first plates 120 face each other) is positioned under the battery cell. For example, referring to FIG. 7, the insertion groove 122 may be recessed into each of the first plates 120 in the X-axis direction (e.g., the insertion groove 122 may extend lengthwise within each of the first plates 120 in the Y-axis direction). According to an embodiment, the jig 100 for evaluating a battery cell may further include a fourth plate 170 that is inserted into the insertion groove 122 and is arranged so as to support the battery cell. In other words, the battery cell may be seated on and supported by an upper surface of the fourth plate 170. Thus, the battery cell may be stably fixed to the jig 100 for evaluating a battery cell. For example, referring to FIG. 7, the fourth plate 170 may be a single continuous plate overlapping the entire bottom of the battery cell or may include multiple plates spaced apart from each other along the Y-axis direction under the bottom of the battery cell (e.g., the fourth plate 170 may be perpendicular to the first plates 120).

According to an embodiment, the fourth plate 170 may include an insulating material. The insulating material may be a material having a resistance such that electricity does not flow through contact with the battery cell. In addition, the insulating material may be a material capable of absorbing heat from the battery cell. Thus, heat of the battery cell may be absorbed by the fourth plate 170, thereby improving the accuracy of performance evaluation of the battery cell.

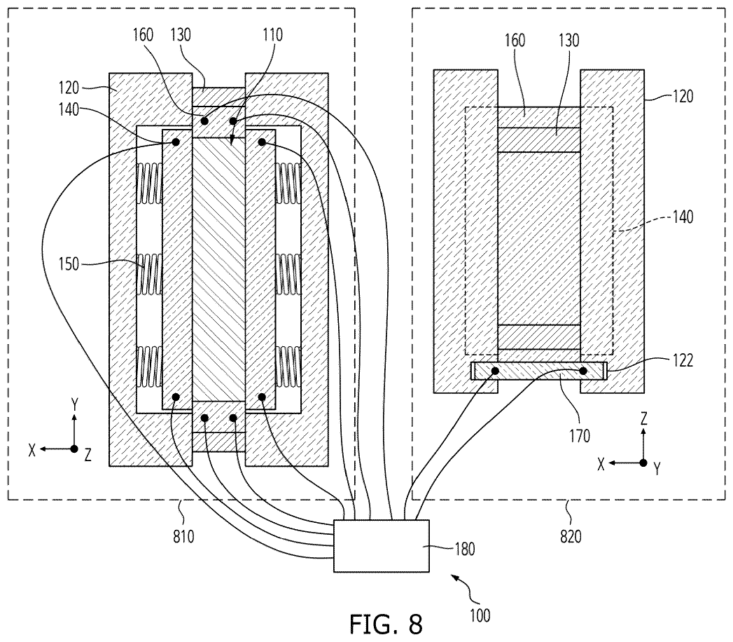

FIG. 8 is a diagram illustrating an example of a jig for evaluating a battery cell, which further includes a cooling device, according to an embodiment of the present disclosure. Descriptions of components described with reference to FIGS. 1 to 7 are omitted here.

FIG. 8 shows, in a view 810 from the Z-axis direction (top view), an example in which the second plate 140 and the third plate 160 are connected to a cooling device 180, and in a view 820 from the Y-axis direction (side view), an example in which the fourth plate 170 is connected to the cooling device 180. The cooling device 180 may include a cooling fluid for cooling the battery cell.

Referring to FIG. 8, the jig 100 for evaluating a battery cell may further include the cooling device 180, which is connected to each of the second plate 140, the third plate 160, and the fourth plate 170. The cooling device 180 may include a water-cooling cooler, an oil-cooling cooler, or an air-cooling cooler.

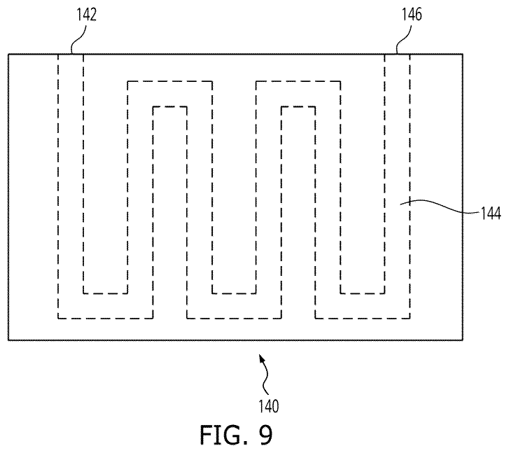

Each of the second plate 140, the third plate 160, and the fourth plate 170 may include an inlet into which a coolant is introduced, a passage through which the introduced coolant flows, and an outlet through which the coolant is discharged from the passage. Details regarding this are described below with reference to FIGS. 9 to 11.

The water-cooling cooler may use water as a coolant to absorb and transfer heat from the battery cell 110. The water-cooling cooler may include a pump, a cooler, cooling water, tubes, and so forth. Thus, the water-cooling cooler may absorb heat from the battery cell 110 by having water absorb heat of the battery cell 110 and then move the water to the cooler to exchange heat with air, after which it is recirculated.

The oil-cooling cooler may use various coolants (e.g., liquids) other than water to absorb and transfer heat from the battery cell 110. The oil-cooling cooler may also include a pump, a cooler, cooling coolant, tubes, and so forth. Thus, the oil-cooling cooler may absorb heat from the battery cell 110 by having the coolant absorb heat of the battery cell 110 and then move the coolant to the cooler to exchange heat with air, after which it is recirculated.

The air-cooling cooler may absorb and transfer heat from the battery cell 110 by using air. The air-cooling cooler may include a heat sink and a fan, etc. Thus, the air-cooling cooler may absorb heat from the battery cell 110 by having the heat sink absorb heat and disperse it over a wide surface area and having the fan blow air to release heat.

According to an embodiment, the cooling device 180 may be connected to the inlets and outlets of each of the second plate 140, the third plate 160, and the fourth plate 170. Accordingly, a coolant may be introduced through an inlet of the second plate 140 and flow through the passage of the second plate 140. The coolant flowing through the passage of the second plate 140 may absorb heat from the long sidewall portions of the battery cell 110. Then, the coolant may be discharged through the outlet of the second plate 140 and be circulated again, thereby absorbing heat of the battery cell 110. A coolant may be introduced through an inlet of the third plate 160 and flow through the passage of the third plate 160. The coolant flowing through the passage of the third plate 160 may absorb heat from the short sidewall portions of the battery cell 110. Then, the coolant may be discharged through the outlet of the third plate 160 and be circulated again, thereby absorbing heat of the battery cell 110. A coolant may be introduced through an inlet of the fourth plate 170 and flow through the passage of the fourth plate 170. The coolant flowing through the passage of the fourth plate 170 may absorb heat from the bottom surface of the battery cell 110. Then, the coolant may be discharged through the outlet of the fourth plate 170 and be circulated again, thereby absorbing heat of the battery cell 110. Consequently, heat of the battery cell 110 may be absorbed by the coolant, thus improving the accuracy of performance evaluation of the battery cell 110.

According to an embodiment, the cooling device 180 may adjust the amount of coolant flowing through each of the second plate 140, the third plate 160, and the fourth plate 170. Therefore, it may be possible to cool different parts of the battery cell 110 differently.

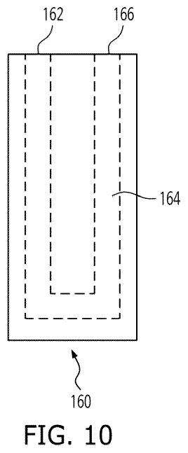

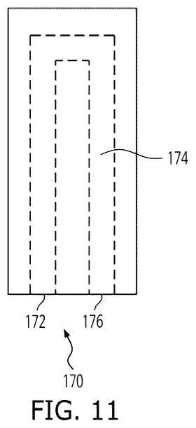

FIG. 9 is a plan view illustrating an example of the second plate 140 according to an embodiment of the present disclosure, FIG. 10 is a plan view illustrating an example of the third plate 160 according to an embodiment of the present disclosure, and FIG. 11 is a plan view illustrating an example of the fourth plate 170 according to an embodiment of the present disclosure.

Referring to FIGS. 9 to 11, each of the second plate 140, the third plate 160, and the fourth plate 170 may include a respective inlet 142, 162, 172 through which a coolant is introduced, a respective passage 144, 164, 174 through which the coolant introduced through the respective inlet 142, 162, 172 flows, and a respective outlet 146, 166, 176 through which the coolant is discharged from the respective passage 144, 164, 174.

For example, the respective inlets 142, 162, 172 and the respective outlets 146, 166, 176 may be formed on the same surface of each of the second plate 140, the third plate 160, and the fourth plate 170. In another example, the respective inlets 142, 162, 172 may be formed on one surface of each plate, and the respective outlets 146, 166, 176 may be formed on another surface of each plate.

According to an embodiment, the respective inlets 142, 162, 172 and the respective outlets 146, 166, 176 may be formed in pairs, respectively, on each of the second plate 140, the third plate 160, and the fourth plate 170. For example, the respective inlets 142, 162, 172 and the respective outlets 146, 166, 176 may be formed as a single pair on each of the second plate 140, the third plate 160, and the fourth plate 170. In another example, the respective inlets 142, 162, 172 and the respective outlets 146, 166, 176 may be formed as two pairs on each of the second plate 140, the third plate 160, and the fourth plate 170.

According to an embodiment, the shape of the respective passages 144, 164, 174 through which the coolant flows may be set in consideration of which part of the battery cell 110 needs to be cooled. For example, the respective passages 144, 164, 174 may be formed in a zigzag shape. However, the shape of the respective passages 144, 164, 174 may vary.

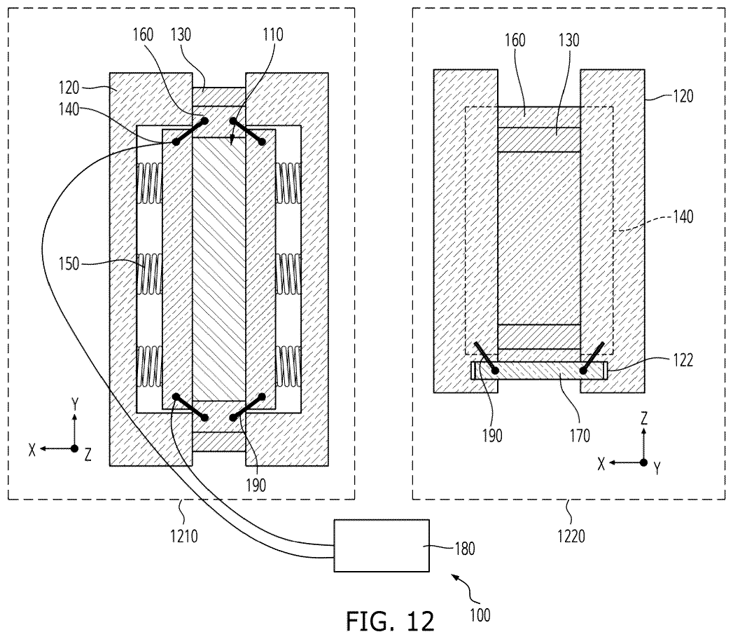

FIG. 12 is a diagram illustrating an example of the jig for evaluating a battery cell, which further includes a cooling device and a connecting pipe, according to an embodiment of the present disclosure. Descriptions of components described with reference to FIGS. 1 to 8 are omitted here.

FIG. 12 shows, in a view 1210 from the Z-axis direction (top view), an example in which the second plate 140 and the third plate 160 are connected to the cooling device 180, and in a view 1220 from the Y-axis direction (side view), an example in which the fourth plate 170 is connected to the cooling device 180.

Referring to FIG. 12, the inlets and outlets of each of the second plate 140, the third plate 160, and the fourth plate 170 may be interconnected by a connecting pipe 190. Therefore, the coolant may flow continuously through the passage of the second plate 140, the passage of the third plate 160, and the passage of the fourth plate 170.

According to an embodiment, the jig 100 for evaluating a battery cell may include the cooling device 180, which is connected to the inlet and outlet of any one of the second plate 140, the third plate 160, and the fourth plate 170. Thus, it may be possible to set an order in which the coolant flows through the second plate 140, the third plate 160, and the fourth plate 170.

For example, the cooling device 180 may be connected to the inlet and outlet of the second plate 140. Therefore, the coolant may flow in order through the passage of the second plate 140, the passage of the third plate 160, and the passage of the fourth plate 170. In another example, the coolant may flow in order through the passage of the second plate 140, the passage of the fourth plate 170, and the passage of the third plate 160.

As yet another example, the cooling device 180 may be connected to the inlet and outlet of the third plate 160. Therefore, the coolant may flow in order through the passage of the third plate 160, the passage of the second plate 140, and the passage of the fourth plate 170. In example, the coolant may flow in order through the passage of the third plate 160, the passage of the fourth plate 170, and the passage of the second plate 140.

As still example, the cooling device 180 may be connected to the inlet and outlet of the fourth plate 170. Therefore, the coolant may flow in order through the passage of the fourth plate 170, the passage of the second plate 140, and the passage of the third plate 160. In another example, the coolant may flow in order through the passage of the fourth plate 170, the passage of the third plate 160, and the passage of the second plate 140.

By way of summation and review, during the charging and discharging and performance evaluation of the secondary battery, the secondary battery may expand, and different stresses may act on different portions of the secondary battery. In addition, there may be temperature variations inside the secondary battery due to heat generation. Thus, a decreased accuracy of the performance evaluation of the secondary battery may occur.

In contrast, the present disclosure provides a jig for evaluating a battery cell that can improve accuracy of performance evaluation of the battery cell. That is, according to some embodiments of the present disclosure, by enabling stress caused by volumetric changes of the battery cell during charging and discharging to be uniformly distributed over the entire surface of the battery cell, the accuracy of performance evaluation of the battery cell may be improved. Further, according to some embodiments of the present disclosure, by absorbing heat generated by the battery cell during charging and discharging, the accuracy of performance evaluation of the battery cell may be improved.

However, the aspects and features of the present disclosure are not limited to the descriptions above, and other aspects and features not mentioned will be clearly understood by those skilled in the art from the detailed description above.

Although embodiments of the present disclosure have been described above, the present disclosure is not limited thereto. Various modifications and variations can be made by those skilled in the art within the spirit of the present disclosure and the equivalent scope of the appended claims.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A jig for evaluating a battery cell, the jig comprising:
first plates arranged to face each other;
a spacer that fixes the first plates to each other;
second plates arranged to face each other, the second plates being between the first plates, and the second plates defining a space therebetween to accommodate the battery cell to be in contact with the second plates; and
an elastic member between each of the first plates and a corresponding one of the second plates.

2. The jig for evaluating a battery cell as claimed in claim 1, wherein the first plates include a metallic material.

3. The jig for evaluating a battery cell as claimed in claim 1, wherein the battery cell includes mutually facing long sidewall portions and mutually facing short sidewall portions, and an area of the long sidewall portions is greater than an area of the short sidewall portions.

4. The jig for evaluating a battery cell as claimed in claim 3, wherein the first plates are arranged to face the long sidewall portions of the battery cell.

5. The jig for evaluating a battery cell as claimed in claim 3, wherein an area of a surface of each of the second plates that faces the battery cell is greater than or equal to an area of a corresponding one of the long sidewall portions.

6. The jig for evaluating a battery cell as claimed in claim 3, wherein the second plates are arranged to be in contact with the long sidewall portions.

7. The jig for evaluating a battery cell as claimed in claim 1, wherein the second plates include at least one of a metallic material and an insulating material.

8. The jig for evaluating a battery cell as claimed in claim 1, wherein, when the battery cell is charged and discharged, the elastic member generates an elastic force in an opposite direction against movement of the second plate caused by a volumetric change of the battery cell.

9. The jig for evaluating a battery cell as claimed in claim 1, wherein the elastic member includes at least one spring.

10. The jig for evaluating a battery cell as claimed in claim 1, wherein the elastic member includes an elastic material.

11. The jig for evaluating a battery cell as claimed in claim 1, further comprising a third plate extending along the spacer, the third plate being between and in contact with the first plates.

12. The jig for evaluating a battery cell as claimed in claim 11, wherein the third plate includes an insulating material.

13. The jig for evaluating a battery cell as claimed in claim 11, wherein each of the first plates includes at least one insertion groove, the at least one insertion groove being recessed in a direction in which the first plates face each other.

14. The jig for evaluating a battery cell as claimed in claim 13, further comprising a fourth plate in the insertion groove, the fourth plate being perpendicular to the first plates and configured to support the battery cell.

15. The jig for evaluating a battery cell as claimed in claim 14, wherein the fourth plate includes an insulating material.

16. The jig for evaluating a battery cell as claimed in claim 14, wherein each of the second plates, the third plate, and the fourth plate includes an inlet, an outlet, and a passage between the inlet and the outlet, the passage accommodating a coolant.

17. The jig for evaluating a battery cell as claimed in claim 16, further comprising a cooling device connected to each of the inlet and the outlet of the second plates, the third plate, and the fourth plate.

18. The jig for evaluating a battery cell as claimed in claim 16, wherein:
the inlet and the outlet of each of the second plates, the third plate, and the fourth plate are connected, such that the coolant flows continuously through the passage of the second plates, the passage of the third plate, and the passage of the fourth plate, and
the jig further includes a cooling device connected to the inlet and the outlet of any one of the second plates, the third plate, and the fourth plate.

19. The jig for evaluating a battery cell as claimed in claim 1, wherein the jig is symmetrical about a center line of the battery cell with respect to a direction intersecting a direction in which the first plates face each other.

20. The jig for evaluating a battery cell as claimed in claim 1, wherein the battery cell includes a pouch-type cell or a prismatic cell.
